(19) United States
(12) Patent Application Publication
(10) Pub. No.: US 2024/0304464 A1
(43) Pub. Date: Sep. 12, 2024

(54) SEMICONDUCTOR PACKAGE AND METHOD OF FABRICATING THE SAME

(71) Applicant: OIP Technology Pte Ltd., Singapore (SG)

(72) Inventor: Yonggang JIN, Singapore (SG)

(21) Appl. No.: 18/297,361

(22) Filed: Apr. 7, 2023

(30) Foreign Application Priority Data
Mar. 7, 2023 (CN) 202310215378.2

(51) Int. Cl. H01L 21/48; H01L 21/56; H01L 23/29; H01L 23/31; H01L 23/367; H01L 23/373; H01L 23/49; H01L 23/492; H01L 25/065

(52) U.S. Cl. CPC H01L 21/4882; H01L 21/4875; H01L 21/568; H01L 23/293; H01L 23/3121; H01L 23/367; H01L 23/3736; H01L 23/49; H01L 23/492; H01L 25/0655

(57) ABSTRACT

A semiconductor package and a method of fabricating the same are disclosed. The method includes: forming a heat sink on back side of at least one die and a vertical access wiring structure adjacently around and spaced apart from the die by printing process; and forming first conductive structure on front side of the plastic encapsulation layer and second conductive structure on back side of the plastic encapsulation layer. The first conductive structure is electrically connected to the die, and the second conductive structure is connected to the heat sink from back side. The first conductive structure is electrically connected to the second conductive structure by the vertical access wiring structure. The vertical access wiring structure is a solid structure, which can overcome problems that may arise from the use of conventional in-hole hollow metal shells that could not withstand large instantaneous currents possibly present in high-power multi-die integration applications.

### CROSS-REFERENCES TO RELATED APPLICATIONS

This application claims the priority of Chinese patent application number 202310215378.2, filed on Mar. 7, 2023, the entire contents of which are incorporated herein by reference.

### TECHNICAL FIELD

The present invention relates to the field of integrated circuit (IC) technology and, in particular, to a semiconductor package and a method of fabricating the semiconductor package.

### BACKGROUND

Interconnection establishment in existing packages or in-substrate vertical interconnects is generally accomplished by laser drilling and metal plating. For a drill hole having a diameter less than 50 μm, it is possible for the plated metal to fill up the hole in the form of a solid metal block. However, for a drill hole with a diameter greater than 150 μm, typically, copper has to be used, and the metal can be typically plated on surfaces of the hole to a thickness of only about 10 μm. Consequently, the copper in the hole appears like a hollow metal shell lining the surfaces of the hole. For high-power multi-die integration applications, such hollow metal shells could not conduct large instantaneous currents that may be present at different sides of the chips. Further, the existing vertical interconnects suffer from poor heat dissipation.

### SUMMARY OF THE INVENTION

It is an objective of the present invention to provide a semiconductor package and a method of fabricating it, which can overcome problems arising from the use of in-hole hollow metal shells that could not conduct large instantaneous currents possibly present in high-power multi-die integration applications, as well as the problem of poor heat dissipation.

To this end, the present invention provides a method of forming a semiconductor package, including the steps of:
providing a carrier substrate with an adhesive layer formed on a surface thereof;
placing at least one die apart on the adhesive layer, wherein each die has opposing front and back sides and is placed with the front side facing the adhesive layer;
forming a heat sink on the back side of the at least one die and a vertical access wiring structure adjacently around and spaced apart from the at least one die by a printing process, the vertical access wiring structure having opposing first and second sides;
filling a plastic encapsulation material between the die and the vertical access wiring structure and curing the plastic encapsulation material to form a plastic encapsulation layer, the plastic encapsulation layer having opposing front and back sides, the front side of the plastic encapsulation layer located on the same side as the front side of the die, the plastic encapsulation layer so formed that the first side of the vertical access wiring structure and the front side of each die are exposed from at the front side thereof and that the second side of the vertical access wiring structure and a surface of the heat sink away from the die are exposed at the back side thereof;
removing the carrier substrate; and
forming a first conductive structure on the front side of the plastic encapsulation layer and a second conductive structure on the back side of the plastic encapsulation layer, the first conductive structure electrically connected to the die from the front side, the second conductive structure connected to the heat sink from the back side, the first conductive structure electrically connected to the second conductive structure by the vertical access wiring structure.

Optionally, the formation of the heat sink and the vertical access wiring structure may include:
in a screen printing process, printing metal paste into a pattern on the back side of the at least one die and curing the metal paste, thereby forming the heat sink; and in the screen printing process, simultaneously printing the metal paste into a pattern around the at least one die and curing the metal paste, thereby forming the vertical access wiring structure.

Additionally, the heat sink may have a thickness of 50 μm to 100 μm.

Additionally, a height of the vertical access wiring structure may be at least equal to a total thickness of the heat sink and the underlying die.

Additionally, the vertical access wiring structure may have a diameter or dimension that is greater than or equal to 150 μm.

Additionally, the metal paste may be curable at a low temperature, and may be, for example, any one of silver paste, tungsten paste, copper paste and gold paste or a combination thereof.

Optionally, the method may further include, prior the removal of the carrier substrate,
forming a number of via holes extending through the plastic encapsulation layer and filling a conductive material in the via holes, thereby forming metal vias, wherein electrical conduction is established between the first conductive structure and the second conductive structure by both the metal vias and the vertical access wiring structure.

In another aspect, the present invention provides a semiconductor package including:
at least one die, which is placed apart and each has opposing front and back sides, wherein the front side of all the at least one die is arranged on the same side;
a heat sink formed on the back side of the at least one die;
a vertical access wiring structure formed around the at least one die, the vertical access wiring structure adjacent to and spaced apart from the die, the vertical access wiring structure having opposing first and second sides, the first side arranged on the same side as the front side of the die;
a plastic encapsulation layer, in which both the die and vertical access wiring structure are embedded, the plastic encapsulation layer having opposing front and back sides, the front side of the plastic encapsulation layer arranged on the same side as the front side of the die, wherein the first side and the front side of each die are exposed at the front side of the plastic encapsulation layer, and the second side and a surface of the heat sink away from the die are exposed at the back side of the plastic encapsulation layer;
a first conductive structure formed on the front side of the plastic encapsulation layer; and
a second conductive structure formed on the back side of the plastic encapsulation layer, wherein the first conductive structure is electrically connected to the second conductive structure by the vertical access wiring structure.

Optionally, the heat sink may have a thickness of 50 μm to 100 μm.

Optionally, a height of the vertical access wiring structure may be at least equal to a total thickness of the heat sink and the underlying die.

Optionally, the vertical access wiring structure may have a diameter or dimension that is greater than or equal to 150 μm.

Optionally, each of the heat sink and the vertical access wiring structure may be made of at least one of gold, silver, copper and tungsten.

Optionally, in the plastic encapsulation layer, a number of metal vias extending therethrough may be formed, wherein electrical conduction is established between the first conductive structure and the second conductive structure by both the metal vias and the vertical access wiring structure.

Compared with the prior art, the present invention offers the following benefits.

The present invention provides a semiconductor package and a method of fabricating it. The method includes the steps of: providing a carrier substrate with an adhesive layer formed on a surface thereof; placing at least one die apart on the adhesive layer, wherein each die has opposing front and back sides and is placed with the front side facing the adhesive layer; forming a heat sink on the back side of the at least one die and a vertical access wiring structure adjacently around and spaced apart from the at least one die by a printing process, the vertical access wiring structure having opposing first and second sides; filling a plastic encapsulation material between the die and the vertical access wiring structure and curing the plastic encapsulation material to form a plastic encapsulation layer, the plastic encapsulation layer having opposing front and back sides, the front side of the plastic encapsulation layer located on the same side as the front side of the die, the plastic encapsulation layer so formed that the first side of the vertical access wiring structure and the front side of each die are exposed from at the front side thereof and that the second side of the vertical access wiring structure and a surface of the heat sink away from the die are exposed at the back side thereof; removing the carrier substrate; and forming a first conductive structure on the front side of the plastic encapsulation layer and a second conductive structure on the back side of the plastic encapsulation layer, the first conductive structure electrically connected to the die from the front side, the second conductive structure connected to the heat sink from the back side, the first conductive structure electrically connected to the second conductive structure by the vertical access wiring structure. The vertical access wiring structure is a solid structure, which can overcome problems that may arise from the use of conventional hollow metal shells that could not withstand large instantaneous currents possibly present in high-power multi-die integration applications. Moreover, the heat sink solves the problem of poor heat dissipation.

### BRIEF DESCRIPTION OF THE DRAWINGS

FIG. 1 is a flowchart of a method of fabricating a semiconductor package according to an embodiment of the present invention.

FIGS. 2A to 2D are schematic diagrams showing structures resulting from steps in a method of fabricating a semiconductor package according to an embodiment of the present invention.

In these figures:

1—carrier substrate; 2—adhesive layer; 100—first die; 200—second die; 310—vertical access wiring structure; 310a—first side; 310b—second side; 320—first heat sink; 330—second heat sink; 400—plastic encapsulation layer; 400a—front side of the plastic encapsulation layer; 400b—back side of the plastic encapsulation layer; 410—metal via; 500—first conductive structure; 510—first metal layer; 600—second conductive structure; 610—second metal layer; 620—third metal connection.

### DETAILED DESCRIPTION

A semiconductor package and a method of fabricating it proposed in the present invention will be described in greater detail below. The present invention will be described in greater detail below with reference to the accompanying drawings, which present preferred embodiments of the invention. It would be appreciated that those skilled in the art can make changes to the invention disclosed herein while still obtaining the beneficial results thereof. Therefore, the following description shall be construed as being intended to be widely known by those skilled in the art rather than as limiting the invention.

For the sake of clarity, not all features of actual implementations are described. In the following, description and details of well-known functions and structures are omitted to avoid unnecessarily obscuring the invention. It should be appreciated that in the development of any such actual implementation, numerous implementation-specific decisions must be made to achieve specific goals of the developers, such as compliance with system-related and business-related constrains, which may vary from one implementation to another. Moreover, it should be appreciated that such a development effort might be complex and time consuming, but would nevertheless be a routine undertaking for those of ordinary skill in the art.

Objectives and features of the present invention will become more apparent upon reading the following more detailed description thereof made with reference to the accompanying drawings and to particular embodiments. Note that the figures are provided in a very simplified form not necessarily drawn to exact scale and for the only purpose of facilitating easy and clear description of the disclosed embodiments.

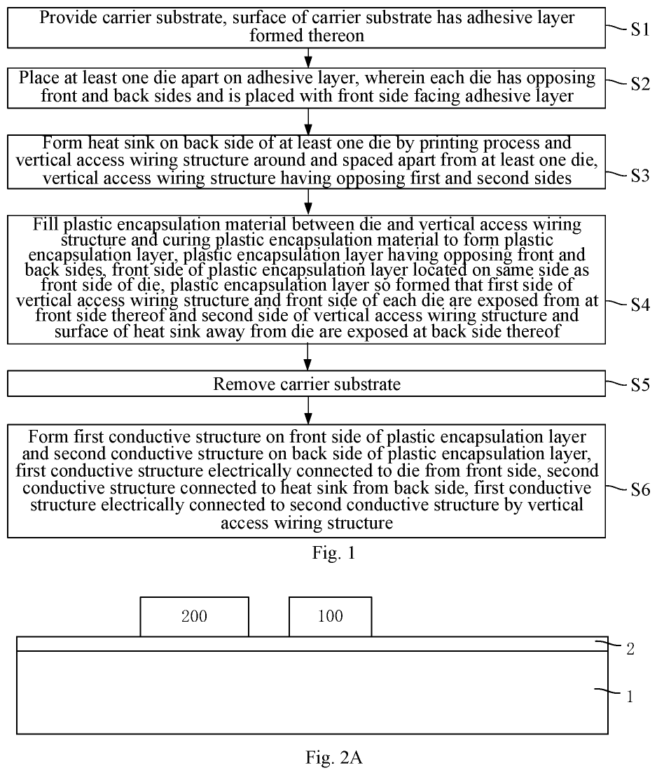

FIG. 1 is a flowchart of a method of fabricating a semiconductor package according to an embodiment of the present invention. As shown in FIG. 1, the method includes the steps of:
step S1: providing a carrier substrate, a surface of the carrier substrate has an adhesive layer formed thereon;
step S2: placing at least one die apart on the adhesive layer, wherein each die has opposing front and back sides and is placed with the front side facing the adhesive layer;
step S3: forming a heat sink on the back side of the at least one die by a printing process and a vertical access wiring structure around and spaced apart from the at least one die, the vertical access wiring structure having opposing first and second sides;
step S4: filling a plastic encapsulation material between the die and the vertical access wiring structure and curing the plastic encapsulation material to form a plastic encapsulation layer, the plastic encapsulation layer having opposing front and back sides, the front side of the plastic encapsulation layer located on the same side as the front side of the die, the plastic encapsulation layer so formed that the first side of the vertical access wiring structure and the front side of each die are exposed from at the front side thereof and that the second side of the vertical access wiring structure and a surface of the heat sink away from the die are exposed at the back side thereof;
step S5: removing the carrier substrate; and
step S6: forming a first conductive structure on the front side of the plastic encapsulation layer and a second conductive structure on the back side of the plastic encapsulation layer, the first conductive structure electrically connected to the die from the front side, the second conductive structure connected to the heat sink from the back side, the first conductive structure electrically connected to the second conductive structure by the vertical access wiring structure.

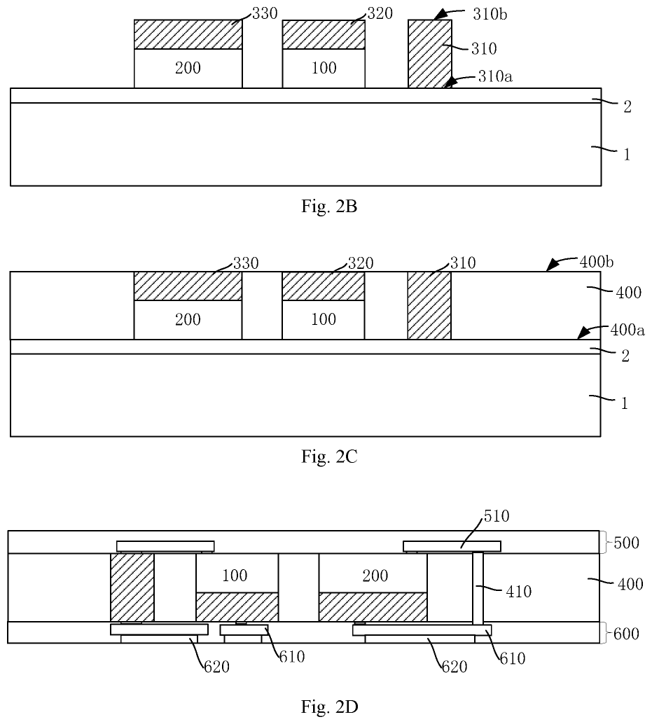

A method of fabricating a semiconductor package according to an embodiment of the present invention will be described in detail below with reference to FIGS. 2A to 2D.

As shown in FIG. 2A, first of all, in step S1, a carrier substrate 1 with an adhesive layer 2 formed on a surface thereof is provided. The carrier substrate 1 is an auxiliary (or temporary) carrier substrate made of, for example, glass, ceramic or a polymer material. Its surface with the adhesive layer 2 formed thereon may be a flat surface in a square or round shape. Additionally, the carrier substrate 1 may be provided at an edge thereof with an encircling wall, and the encircling wall may be configured as a detachable structure.

With continued reference to FIG. 2A, subsequently, in step S2, at least one die is placed apart on the adhesive layer 2. Each die has opposing front and back sides and is placed with the front side facing the adhesive layer 2. The die may be an image sensor die, power die or any of various dies to be packaged. The die may have a first input/output port (not shown) arranged on the front side thereof. Optionally, the die may additionally have a second input/output port (not shown) arranged on the back side thereof.

With continued reference to FIG. 2A, in this embodiment, two dies (i.e., a first die 100 and a second die 200) are placed apart on the adhesive layer 2. Each of the dies 100, 200 has opposing front and back sides. The front sides of the dies 100, 200 are both oriented to face the adhesive layer 2. Each of the dies 100, 200 has a first input/output port and a second input/output port.

As shown in FIG. 2B, afterward, in step S3, a heat sink is formed on the back side of the at least one die by a printing process, and a vertical access wiring structure 310 around and spaced apart from the at least one die. The vertical access wiring structure 310 has opposing first 310a and second 310b sides.

Each die may be provided therearound with at least one such vertical access wiring structure 310, and the number of the vertical access wiring structure(s) 310 may be appropriately determined as needed. Moreover, it is possible either that only one die is provided therearound with such vertical access wiring structure(s) 310, or that some or all of the die(s) are each provided therearound with such vertical access wiring structure(s) 310. That is, if necessary, each die may be provided therearound with at least one such vertical access wiring structure 310. In this embodiment, one of the dies is provided therearound with one vertical access wiring structure 310, as an example.

In particular, a screen printing process may be employed, in which metal paste is printed into a pattern on the back side of the at least one die and cured, thereby forming the heat sink. In the screen printing process, the metal paste may be additionally printed into a pattern around the at least one die and cured, thereby forming the vertical access wiring structure spaced apart from the die. The vertical access wiring structure has opposing first 310a and second 310b sides.

The vertical access wiring structure 310 is intended to establish an electrical interconnection between the front and back sides of the die. The vertical access wiring structure 310 is a solid structure, which can overcome problems that may arise from the use of conventional thin metal films (in the form of hollow metal shells) formed in drill holes that could not withstand large instantaneous currents possibly present in high-power multi-die integration applications, as well as the problem of poor heat dissipation.

The heat sink has a thickness of 50 μm to 100 μm, which can facilitate heat dissipation and enables the vertical access wiring structure to have a height that is at least equal to a total thickness of the heat sink and the underlying die.

The heat sink may be electrically connected to the back side of the underlying die. More precisely, it may be electrically connected to the underlying second input/output port. The vertical access wiring structure 310 may be, for example, square or round post. The vertical access wiring structure 310 has a diameter or dimension that is greater than or equal to 150 μm. Additionally, the diameter or dimension of the vertical access wiring structure 310 may be greater than or equal to 200 μm, making the vertical access wiring structure 310 applicable to large via hole packaging applications, without problems that may arise from the use of hollow metal shells for interconnection, which could not withstand large currents.

The metal paste may be curable at a low temperature. For example, it may be, for example, any of silver paste, tungsten paste, copper paste and gold paste, or a combination thereof.

With continued reference to FIG. 2B, in this embodiment, in the screen printing process, the metal paste is printed into a pattern on the back side of the first die 100 and cured, thereby forming a first heat sink 320. Moreover, in the screen printing process, the metal paste is printed into a pattern on the back side of the second die 200 and cured, thereby forming a second heat sink 330. Further, in the screen printing process, the metal paste is printed into a pattern around the first die 100 and cured, thereby forming a vertical access wiring structure 310 that is adjacent to and spaced apart from the die 100.

In alternative embodiments, in the screen printing process, the metal paste may be printed into a pattern on the back side of the first or second die and cured, thereby forming the first or second heat sink. Moreover, in the screen printing process, the metal paste may be printed into a pattern around the first die and cured, thereby forming at least one first vertical access wiring structure. Further, in the screen printing process, the metal paste may be printed into a pattern around the second die and cured, thereby forming at least one second vertical access wiring structure.

As shown in FIG. 2C, after that, in step S4, a plastic encapsulation material is filled and cured between the die and the vertical access wiring structure 310, thereby forming a plastic encapsulation layer 400. The plastic encapsulation layer 400 has opposing front 400a and back 400b sides. The front side 400a of the plastic encapsulation layer 400 is located on the same side as the front side of the die. The plastic encapsulation layer 400 is so formed that the first side 310a of the vertical access wiring structure 310 and the front side of each die are exposed at the front side 400a thereof and that the second side 310b of the vertical access wiring structure 310 and a surface of the heat sink away from the die are exposed at the back side 400b thereof.

Examples of the plastic encapsulation material may include materials absorbing at least part of light that travels therethrough, light-reflective materials, light-scattering materials, insulating materials translucent or opaque to visible light (e.g., at a wavelength in the range of 380-750 nm) and insulating materials that are almost non-transmissive to infrared rays (e.g., at a wavelength in the range of 750 nm to 1 mm). Non-limiting examples of the plastic encapsulation material may include thermoplastic resins such as polycarbonate (PC), polyethylene terephthalate (PET), polyethersulfone, polyphenylether, polyamide, polyetherimide, methacrylic and cyclic polyolefins, thermosetting resins such as epoxy, phenol, polyurethane, acrylic, vinyl ester, imide-based, polyurethane-based, urea or melamine resins, and organic insulating materials such as polystyrene and polyacrylonitrile.

In alternative embodiments, non-limiting examples of the plastic encapsulation material may include inorganic insulating materials such as inorganic oxides and nitrides such as silicon oxide, silicon nitride, silicon oxynitride, aluminum oxide, titanium oxide, tantalum oxide or zinc oxide.

In still alternative embodiment, non-limiting examples of the plastic encapsulation material may include opaque materials such as black matrix materials. Examples of the black matrix materials may include organic resins and resins or pastes containing glass slurry and a black pigment.

In this embodiment, the plastic encapsulation material preferably includes a thermosetting resin such as an epoxy resin, which can ensure good planeness of the plastic encapsulation layer 400 when heated and hence of the die.

Next, in step S5, the carrier substrate 1 is removed.

In this embodiment, each die is attached to the carrier substrate 1 by the adhesive, which is, for example, a hot melt adhesive. Accordingly, the carrier substrate 1 may be removed by heating the carrier substrate 1 and thereby varying adhesiveness of the hot melt adhesive. It is to be noted that the hot melt adhesive is desirably heated at a temperature lower than a curing temperature of the plastic encapsulation layer 400, in order to avoid otherwise affecting the plastic encapsulation layer 400.

In another embodiment, the adhesive may have variable adhesiveness, and laser, infrared radiation, ultrasonic waves or the like may be utilized to locate the adhesive. The carrier substrate may be heated to deteriorating the adhesiveness, allowing removal of the carrier substrate. In yet another embodiment, forces may be additionally applied to the back sides of the carrier substrate and the plastic encapsulation layer to urge them to move in opposite directions, thereby removing the carrier substrate. However, the present invention is not limited thereto. For example, the carrier substrate may also be removed by laser lift-off, mechanical cutting or otherwise.

After that, in step S6, a first conductive structure 500 is formed on the front side of the plastic encapsulation layer 400, and a second conductive structure 600 on the back side of the plastic encapsulation layer 400. The first conductive structure 500 is electrically connected to the die from the front side, and the second conductive structure 600 to the heat sink from the back side. Moreover, the first conductive structure 500 is electrically connected to the second conductive structure 600 by the vertical access wiring structure 310.

Specifically, when the vertical access wiring structure(s) 310 does/do not suffice to satisfy all the electrical connection needs on the front and back sides of the die(s), a number of via holes extending through the plastic encapsulation layer 400 may be formed by mechanical or laser drilling, dry etching or otherwise. An appropriate approach may be chosen according to the material properties of the plastic encapsulation layer 400 to form the via holes. In this embodiment, in case of the plastic encapsulation layer 400 being made of epoxy resin, a laser drilling process may be utilized to form the via holes therein. The via holes may be formed around at least some of the die(s), and a conductive material may be filled in the via holes, forming metal vias 410. Thus, the first conductive structure is connected to the second conductive structure by both the metal vias 410 and the vertical access wiring structure(s). All possible large instantaneous currents are conducted between the first and second conductive structures through the vertical access wiring structure(s), rather than through the metal vias 410. The via holes may have a diameter much smaller than the diameter or dimension of the vertical access wiring structure(s) 310.

The conductive material may be, for example, a metal such as copper (Cu), tungsten (W), silver (Ag), gold (Au) or the like, a conductive alloy or a conductive adhesive.

With continued reference to FIG. 2D, the formation of the first conductive structure 500 may include the steps as follows.

First of all, a first passivation layer covering the front side 400a of the plastic encapsulation layer 400 is formed, and first connection holes are formed in the first passivation layer, in which the first input/output port(s) of all the die(s), the metal via(s) 410 and first end face(s) 310a of the vertical access wiring structure(s) 310 are exposed. A conductive material is then electroplated in the first connection holes, forming first metal connections.

Next, a first metal layer 510 is formed on the first passivation layer. The first metal layer 510 includes multiple first pads residing on different portions of the first passivation layer. The multiple first pads are connected to all of the first input/output port(s), the metal vias 410 and the first end face(s) 310a of the vertical access wiring structure(s) 310 by the respective first metal connections.

After that, a second passivation layer is formed, which covers both the first passivation layer and the first metal layer 510. The first and second passivation layers are intended to electrically isolate the first metal layer 510 to prevent the occurrence of a short circuit therein.

Each of the first and second passivation layers is an insulating material such as a polymer material. Additionally, the polymer material may be, for example, any one of polyimide, benzocyclobutene (BCB) and polybenzobisoxazole (PBO), or a combination thereof. The first and second passivation layers may be made of the same material, or different materials. In this embodiment, both the first and second passivation layers are made of the same material, which is, for example, polyimide.

The first metal layer 510 may be an inorganic material, such as a metal such as Cu, Ag, W, Au or the like, a conductive alloy, a conductive oxide (e.g., ITO), etc. Alternatively, it may be a conductive organic material such as a conductive polymer. The first metal layer 510 may have a thickness of about 3 microns to 10 microns, preferably 3 microns to 5 microns, on a surface of the first passivation layer.

The formation of the second conductive structure 600 may include the steps as follows.

First of all, a third passivation layer covering the back side 400b of the plastic encapsulation layer 400 is formed, and second connection holes are formed in the third passivation layer, in which portions of the surface of the heat sink away from the die(s), second end face(s) 310b of the vertical access wiring structure(s) 310 and the metal vias 410 are exposed. A conductive material is then electroplated in the second connection holes, forming second metal connections.

Next, a second metal layer 610 is formed on the third passivation layer. The first metal layer 510 includes multiple second pads residing on different portions of the second passivation layer. The multiple second pads are connected to all of the heat sink, the metal vias 410 and the second end face(s) 310b of the vertical access wiring structure(s) 310 by the respective second metal connections.

After that, a fourth passivation layer is formed, which covers both the third passivation layer and the second metal layer 610. The third and fourth passivation layers are intended to electrically isolate the second metal layer 610 to prevent the occurrence of a short circuit therein.

Subsequently, third metal connections 620 are formed by creating multiple third connection holes in the fourth passivation layer, in which the second metal layer 610 is exposed, and then filling a conductive material in the multiple third connection holes. The third metal connections 620 are provided for electrical connection with an external circuit (e.g., a PCB or FPC board).

With continued reference to FIGS. 2A to 2D, in embodiments of the present invention, there is also provided a semiconductor package including at least one die placed apart, each having opposing front and back sides. The front side(s) of all the die(s) is/are arranged on the same side.

A heat sink is formed on the back side of the at least one die, and a vertical access wiring structure 310 is formed around the at least one die. The vertical access wiring structure 310 is spaced apart from the die. The vertical access wiring structure 310 has opposing first 310a and second 310b sides, and the first side 310a is arranged on the same side as the front side of the die.

A plastic encapsulation layer 400 is filled between the die and the vertical access wiring structure 310 so that both the die and the vertical access wiring structure 310 are embedded in the plastic encapsulation layer 400. The plastic encapsulation layer 400 has opposing front 400a and back 400b sides, and the front side 400a of the plastic encapsulation layer 400 is arranged on the same side as the front side of the die. The first side 310a of the vertical access wiring structure and the front side of each die is exposed at the front side 400a of the plastic encapsulation layer, and both the second side 310b of the vertical access wiring structure and a surface of the heat sink away from the die are exposed at the back side 400b of the plastic encapsulation layer.

A plurality of metal vias 410 are formed in the plastic encapsulation layer 400. The metal vias 410 extends through the plastic encapsulation layer 400. A first conductive structure 500 is formed on the front side 400a of the plastic encapsulation layer, and a second conductive structure 600 on the back side 400b of the plastic encapsulation layer. The first conductive structure 500 is electrically connected to the second conductive structure 600 by both the vertical access wiring structure 310 and the plurality of metal vias 410.

The first conductive structure 500 includes a first passivation layer, a first metal layer 510 and a second passivation layer, which are sequentially stacked on the front side 400a of the plastic encapsulation layer. The first passivation layer resides on the front side 400a of the plastic encapsulation layer, and a first input/output port in each die, the metal vias 410 and a first end face 310a of the vertical access wiring structure 310 are all exposed from the first passivation layer. Moreover, first metal connections are exposed at the front side 400a of the plastic encapsulation layer 110. The first metal layer 310 resides on the first passivation layer and includes a plurality of first pads residing on different portions of the first passivation layer. The first pads are connected to all of the first input/output port, the metal vias 410 and the first end face 310a of the vertical access wiring structure 310 through the respective first metal connections. The second passivation layer covers both the first passivation layer and the first metal layer 310. The first and second passivation layers are intended to electrically isolate the first metal layer 310 to prevent the occurrence of a short circuit therein.

The second conductive structure 600 includes a third passivation layer, a second metal layer 610 and a fourth passivation layer, which are sequentially stacked on the back side 400b of the plastic encapsulation layer. In the third passivation layer, second connection holes are formed, in which all of portions of the surface of the heat sink away from the die, a second end face 310b of the vertical access wiring structure 310 and the metal vias 410 are exposed. A conductive material is electroplated in the second connection holes, forming second metal connections.

The second metal layer 610 resides on the third passivation layer and includes a plurality of second pads residing on different portions of the second passivation layer. The second pads are connected to all of the heat sink, the metal vias 410 and the second end face 310b of the vertical access wiring structure 310 through the respective second metal connections.

The fourth passivation layer covers the third passivation layer and the second metal layer 610. The third and fourth passivation layers are intended to electrically isolate the second metal layer 610 to prevent the occurrence of a short circuit therein. A plurality of third metal connections 620 connected to the second metal layer are formed in the fourth passivation layer. The third metal connections 620 are configured for electrical connection with an external circuit (e.g., a PCB or FPC board).

In summary, the present invention provides a semiconductor package and a method of fabricating it. The method includes the steps of: providing a carrier substrate with an adhesive layer formed on a surface thereof; placing at least one die apart on the adhesive layer, wherein each die has opposing front and back sides and is placed with the front side facing the adhesive layer; forming a heat sink on the back side of the at least one die and a vertical access wiring structure adjacently around and spaced apart from the at least one die by a printing process, the vertical access wiring structure having opposing first and second sides; filling a plastic encapsulation material between the die and the vertical access wiring structure and curing the plastic encapsulation material to form a plastic encapsulation layer, the plastic encapsulation layer having opposing front and back sides, the front side of the plastic encapsulation layer located on the same side as the front side of the die, the plastic encapsulation layer so formed that the first side of the vertical access wiring structure and the front side of each die are exposed from at the front side thereof and that the second side of the vertical access wiring structure and a surface of the heat sink away from the die are exposed at the back side thereof; removing the carrier substrate; and forming a first conductive structure on the front side of the plastic encapsulation layer and a second conductive structure on the back side of the plastic encapsulation layer, the first conductive structure electrically connected to the die from the front side, the second conductive structure connected to the heat sink from the back side, the first conductive structure electrically connected to the second conductive structure by the vertical access wiring structure. The vertical access wiring structure is a solid structure, which can overcome problems that may arise from the use of conventional hollow metal shells that could not withstand large instantaneous currents possibly present in high-power multi-die integration applications. Moreover, the heat sink solves the problem of poor heat dissipation.

It is to be noted that, as used herein, the terms “first” and “second” are only meant to distinguish various components, elements, steps, etc. from each other rather than indicate logical or sequential orderings thereof, unless otherwise indicated or specified.

It is to be understood that while the invention has been described above with reference to preferred embodiments thereof, it is not limited to these embodiments. In light of the above teachings, any person familiar with the art may make many possible modifications and variations to the disclosed embodiments or adapt them into equivalent embodiments, without departing from the scope of the invention. Accordingly, it is intended that any and all simple variations, equivalent changes and modifications made to the foregoing embodiments based on the substantive disclosure of the invention without departing from the scope thereof fall within this scope.

What is claimed is:

1. A method of forming a semiconductor package, comprising the steps of:
providing a carrier substrate, a surface of the carrier substrate having an adhesive layer formed thereon;
placing at least one die apart on the adhesive layer, wherein each die has opposing front and back sides and is placed with the front side facing the adhesive layer;
forming a heat sink on the back side of the at least one die and a vertical access wiring structure adjacently around and spaced apart from the at least one die by a printing process, the vertical access wiring structure having opposing first and second sides;
filling a plastic encapsulation material between the die and the vertical access wiring structure and curing the plastic encapsulation material to form a plastic encapsulation layer, the plastic encapsulation layer having opposing front and back sides, the front side of the plastic encapsulation layer located on a same side as the front side of the die, the first side of the vertical access wiring structure and the front side of each die are exposed from at the front side of the plastic encapsulation layer, the second side of the vertical access wiring structure and a surface of the heat sink away from the die are exposed at the back side of the plastic encapsulation layer;
removing the carrier substrate; and
forming a first conductive structure on the front side of the plastic encapsulation layer and a second conductive structure on the back side of the plastic encapsulation layer, the first conductive structure electrically connected to the die from the front side, the second conductive structure connected to the heat sink from the back side, the first conductive structure electrically connected to the second conductive structure by the vertical access wiring structure.

2. The method of claim 1, wherein the formation of the heat sink and the vertical access wiring structure comprises:
in a screen printing process, printing metal paste into a pattern on the back side of the at least one die and curing the metal paste, thereby forming the heat sink; and in the screen printing process, simultaneously printing the metal paste into a pattern around the at least one die and curing the metal paste, thereby forming the vertical access wiring structure.

3. The method of claim 2, wherein the heat sink has a thickness of 50 μm to 100 μm.

4. The method of claim 2, wherein a height of the vertical access wiring structure is at least equal to a total thickness of the heat sink and the underlying die.

5. The method of claim 2, wherein the vertical access wiring structure has a diameter or dimension that is greater than or equal to 150 μm.

6. The method of claim 2, wherein the metal paste is curable at a low temperature and is any one of silver paste, tungsten paste, copper paste and gold paste or a combination thereof.

7. The method of claim 1, further comprising, prior the removal of the carrier substrate,
forming a number of via holes extending through the plastic encapsulation layer and filling a conductive material in the via holes, thereby forming metal vias, wherein electrical conduction is established between the first conductive structure and the second conductive structure by both the metal vias and the vertical access wiring structure.

8. A semiconductor package, comprising:
at least one die, which is placed apart and each has opposing front and back sides, wherein the front side of all the at least one die is arranged on a same side;
a heat sink formed on the back side of the at least one die;
a vertical access wiring structure formed around the at least one die, the vertical access wiring structure adjacent to and spaced apart from the die, the vertical access wiring structure having opposing first and second sides, the first side arranged on the same side as the front side of the die;
a plastic encapsulation layer, in which both the die and vertical access wiring structure are embedded, the plastic encapsulation layer having opposing front and back sides, the front side of the plastic encapsulation layer arranged on the same side as the front side of the die, wherein the first side and the front side of each die are exposed at the front side of the plastic encapsulation layer, and the second side and a surface of the heat sink away from the die are exposed at the back side of the plastic encapsulation layer;
a first conductive structure formed on the front side of the plastic encapsulation layer; and
a second conductive structure formed on the back side of the plastic encapsulation layer, wherein the first conductive structure is electrically connected to the second conductive structure by the vertical access wiring structure.

9. The semiconductor package of claim 8, wherein the heat sink has a thickness of 50 μm to 100 μm.

10. The semiconductor package of claim 8, wherein a height of the vertical access wiring structure is at least equal to a total thickness of the heat sink and the underlying die.

11. The semiconductor package of claim 8, wherein the vertical access wiring structure has a diameter or dimension that is greater than or equal to 150 μm.

12. The semiconductor package of claim 8, wherein each of the heat sink and the vertical access wiring structure is made of at least one of gold, silver, copper and tungsten.

13. The semiconductor package of claim 8, wherein in the plastic encapsulation layer, a number of metal vias extending therethrough are formed, and wherein electrical conduction is established between the first conductive structure and the second conductive structure by both the metal vias and the vertical access wiring structure.
